(19) United States
(12) Patent Application Publication
(10) Pub. No.: US 2024/0267012 A1
(43) Pub. Date: Aug. 8, 2024

(54) POWER AMPLIFIER CIRCUIT AND COMMUNICATION DEVICE

(71) Applicant: Murata Manufacturing Co., Ltd., Nagaokakyo-shi (JP)

(72) Inventors: Makoto ITOU, Nagaokakyo-shi (JP); Yuri HONDA, Nagaokakyo-shi (JP)

(73) Assignee: Murata Manufacturing Co., Ltd., Nagaokakyo-shi (JP)

(21) Appl. No.: 18/638,724

(22) Filed: Apr. 18, 2024

Related U.S. Application Data
(63) Continuation of application No. PCT/JP2022/044291, filed on Nov. 30, 2022.

(30) Foreign Application Priority Data
Dec. 8, 2021 (JP) 2021-199041

(51) Int. Cl. H03F 3/24; H03F 1/08; H04B 1/04

(52) U.S. Cl. CPC H03F 3/245; H03F 1/086; H04B 1/0458; H03F 2200/294; H03F 2200/451

(57) ABSTRACT

A power amplifier circuit includes a power supply terminal and an amplifier transistor that has a base terminal, a collector terminal connected to the power supply terminal, and an emitter terminal and that performs power amplification of a radio-frequency input signal input through the base terminal to output a radio-frequency signal subjected to the power amplification from the collector terminal. The amplifier transistor receives first bias current via the base terminal assuming a first power supply voltage is applied to the power supply terminal and receives second bias current smaller than the first bias current via the base terminal assuming a second power supply voltage higher than the first power supply voltage is applied to the power supply terminal.

### CROSS-REFERENCE TO RELATED APPLICATIONS

This is a continuation application of PCT/JP2022/044291, filed on Nov. 30, 2022, designating the United States of America, which is based on and claims priority to Japanese Patent Application No. JP 2021-199041 filed on Dec. 8, 2021. The entire contents of the above-identified applications, including the specifications, drawings and claims, are incorporated herein by reference in their entirety.

### TECHNICAL FIELD

The present disclosure relates to a power amplifier circuit and a communication device.

### BACKGROUND ART

Envelop tracking (ET) has been applied to power amplifier circuits to attempt to improve power-added efficiency in recent years. In the ET, a technique for analog ET (for example, refer to Patent Document 1) to supply power supply voltage having a continuously varying voltage level and a technique for digital ET (for example, refer to Patent Document 2) to supply power supply voltage having multiple discrete voltage levels are disclosed.

### CITATION LIST

### Patent Document

Patent Document 1: U.S. patent Application Publication No. 2020/0076375
Patent Document 2: U.S. Pat. No. 8,829,993

### Summary of Disclosure

### Technical Problem

However, since the gain difference of the power amplifier circuit with respect to the variation in the voltage level of the power supply voltage is large assuming the power amplifier circuit is operated in the digital ET method to optimize the power-added efficiency, amplification characteristics, such as backoff and signal distortion, may be degraded.

In order to resolve the above problem, the present disclosure provides a power amplifier circuit and a communication device, which reduce the gain difference in the digital ET method.

### Solution to Problem

In order to achieve the above object, a power amplifier circuit according to one aspect of the present disclosure includes a power supply terminal, and an amplifier transistor that has a first control terminal, a first terminal connected to the power supply terminal, and a second terminal and that performs power amplification of a radio-frequency input signal input through the first control terminal to output a radio-frequency signal subjected to the power amplification from the first terminal. The amplifier transistor receives first bias current via the first control terminal assuming a first power supply voltage is applied to the power supply terminal and receives second bias current smaller than the first bias current via the first control terminal assuming a second power supply voltage higher than the first power supply voltage is applied to the power supply terminal.

A power amplifier circuit according to one aspect of the present disclosure includes a power supply terminal, an amplifier transistor that has a first control terminal, a first terminal connected to the power supply terminal, and a second terminal and that performs power amplification of a radio-frequency input signal input through the first control terminal to output a radio-frequency signal subjected to the power amplification from the first terminal, and a bias circuit that outputs bias current. The bias circuit includes a first transistor that has a third terminal, a fourth terminal, and a second control terminal and that supplies the bias current from the fourth terminal to the first control terminal, a current terminal that is connected to the second control terminal and that receives constant current, a second transistor which has a fifth terminal, a sixth terminal, and a third control terminal and the fifth terminal and the third control terminal of which are connected to the power supply terminal, a third transistor which has a seventh terminal, an eighth terminal, and a fourth control terminal, the seventh terminal of which is connected to the second control terminal, and the fourth control terminal of which is connected to the sixth terminal, and a fourth transistor which has a ninth terminal, a tenth terminal, and a fifth control terminal, the ninth terminal of which is connected to the eighth terminal, and the tenth terminal of which is grounded.

### Effects of Disclosure

According to the present disclosure, it is possible to provide a power amplifier circuit and a communication device, which reduce the gain difference in the digital ET method.

### BRIEF DESCRIPTION OF DRAWINGS

FIG. 1 is a diagram illustrating the circuit configurations of a power amplifier circuit and a communication device according to an embodiment.

FIG. 2 is a circuit block diagram of the power amplifier circuit and a power supply circuit according to the embodiment.

FIG. 3 is a diagram illustrating the circuit configuration of a power amplifier according to the embodiment.

FIG. 4 is a graph indicating the relationship between power supply voltage and bias current in the power amplifier circuit according to the embodiment.

FIG. 5A is a graph indicating an example of transition of the power supply voltage in a digital ET mode.

FIG. 5B is a graph indicating an example of transition of the power supply voltage in an analog ET mode.

FIG. 5C is a graph indicating an example of transition of the power supply voltage in an average power tracking mode.

FIG. 6A is a graph indicating the relationship between output power and gain in the digital ET mode of a power amplifier circuit according to a comparative example.

FIG. 6B is a graph indicating the relationship between the output power and the gain in the digital ET mode of the power amplifier circuit according to the embodiment.

FIG. 7 is a diagram illustrating the circuit configuration of a power amplifier according to a first modification.

FIG. 8 is a diagram illustrating the circuit configuration of a power amplifier circuit according to a second modification.

FIG. 9 is a graph indicating the relationship between the power supply voltage and the bias current in the power amplifier circuit according to the second modification.

### DESCRIPTION OF EMBODIMENTS

Embodiments of the present disclosure will herein be described in detail with reference to the drawings. All the embodiments described below indicate comprehensive or specific examples. Numerical values, shapes, materials, components, the arrangement of the components, the connection mode of the components, and so on, which are indicated in the embodiments described below, are only examples and are not intended to limit the present disclosure.

The respective drawings are schematic diagrams appropriately subjected to emphasis, omission, or adjustment of ratios in order to describe the present disclosure. The respective drawings are not necessarily strictly illustrated and may be different from the actual shapes, positional relationship, and ratios. The same reference numerals and letters are used in the respective drawings to identify substantially the same components and a duplicated description of such components may be omitted or simplified.

In the circuit configurations of the present disclosure, “connected” includes not only direct connection with a connection terminal and/or a wiring conductor but also electrical connection via another circuit element. “Connected between A and B” means connection to both A and B between A and B and means series connection to a path between A and B.

### Embodiments

### [1. Circuit Configurations of Power Amplifier Circuit 1 and Communication Device 7]

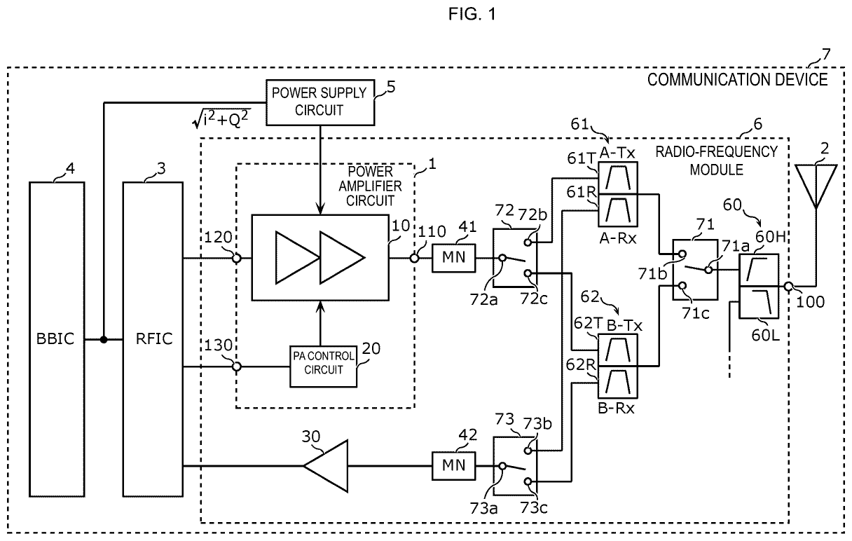

The circuit configurations of a power amplifier circuit 1 and a communication device 7 according to the present embodiment will now be described with reference to FIG. 1.

FIG. 1 is a diagram illustrating the circuit configurations of the power amplifier circuit 1 and the communication device 7 according to the present embodiment.

### [1.1 Circuit Configuration of Communication Device 7]

First, the circuit configuration of the communication device 7 will be described. As illustrated in FIG. 1, the communication device 7 according to the present embodiment includes a radio-frequency module 6, an antenna 2, a radio-frequency integrated circuit (RFIC) 3, a baseband integrated circuit (BBIC) 4, and a power supply circuit 5.

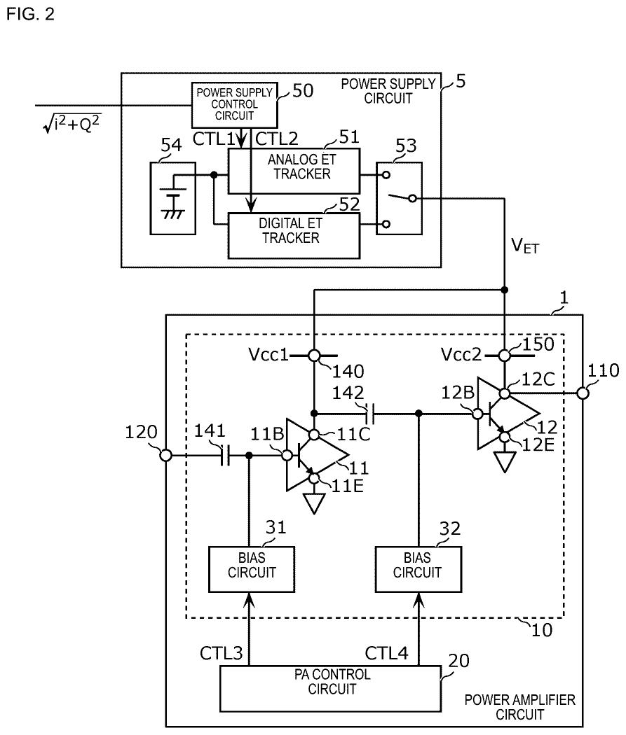

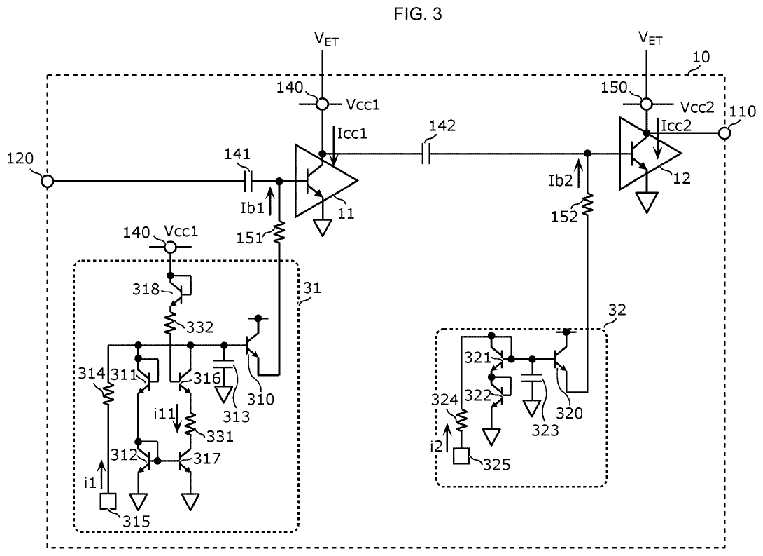

The radio-frequency module 6 includes the power amplifier circuit 1, a low-noise amplifier 30, duplexers 61 and 62, a diplexer 60, matching circuits 41 and 42, and switches 71, 72, and 73. The radio-frequency module 6 transmits a radio-frequency signal between the antenna 2 and the RFIC 3. The configuration of the power amplifier circuit 1 will be described below with reference to FIG. 2 and FIG. 3.

The antenna 2 is connected to an antenna connection terminal 100 of the radio-frequency module 6. The radio-frequency signal output from the radio-frequency module 6 is transmitted from the antenna 2 and the radio-frequency signal is received from the outside of the radio-frequency module 6 through the antenna 2 to be supplied to the radio-frequency module 6.

The RFIC 3 is an example of a signal processing circuit that processes the radio-frequency signal. Specifically, the RFIC 3 performs signal processing, such as down-conversion, to a radio-frequency reception signal input through a receive path of the radio-frequency module 6 and supplies a reception signal resulting from the signal processing to the BBIC 4. In addition, the RFIC 3 performs signal processing, such as up-conversion, to a transmission signal input from the BBIC and supplies a radio-frequency transmission signal resulting from the signal processing to a transmit path of the radio-frequency module 6. The RFIC 3 includes a control unit that controls the radio-frequency module 6. Part or all of the functions of the RFIC 3 serving as the control unit may be installed outside the RFIC 3. For example, part or all of the functions of the RFIC 3 serving as the control unit may be installed in the BBIC 4 or the radio-frequency module 6.

The BBIC 4 is a baseband signal processing circuit that performs signal processing using an intermediated frequency band lower than the frequencies of the radio-frequency signals transmitted by the radio-frequency module 6. For example, an image signal for image display and/or an audio signal for talking with a speaker is used as the signal processed in the BBIC 4.

The power supply circuit 5 supplies power supply voltage V_{ET} to the power amplifier circuit 1. The configuration of the power supply circuit 5 will be described below with reference to FIG. 2.

The circuit configuration of the communication device 7 illustrated in FIG. 1 is only an example and is not limited to this. For example, the communication device 7 does not necessarily include the antenna 2 and/or the BBIC 4. For example, the communication device 7 may include multiple antennas.

### [1.2 Circuit Configuration of Radio-Frequency Module 6]

Next, the circuit configuration of the radio-frequency module 6 will be described.

The power amplifier circuit 1 has an input terminal 120 through which the radio-frequency transmission signal is input, an output terminal 110 through which the radio-frequency transmission signal (hereinafter referred to as the transmission signal) is output, and a control terminal 130 through which a control signal is received.

The switch 71 is connected between the antenna connection terminal 100 and the duplexers 61 and 62. The switch 71 has terminals 71a, 71b, and 71c. The terminal 71a is connected to the antenna connection terminal 100 via the diplexer 60. The terminal 71b is connected to the duplexer 61 and the terminal 71c is connected to the duplexer 62.

In this connection configuration, the switch 71 is capable of connecting the terminal 71a to either of the terminals 71b and 71c based on, for example, a control signal from the RFIC 3. In other words, the connection of the antenna connection terminal 100 is capable of being switched between the duplexers 61 and 62 with the switch 71. The switch 71 is composed of, for example, a single-pole double-throw (SPDT) switch circuit.

The switch 72 is connected between transmission filters 61T and 62T and the power amplifier circuit 1. The switch 72 has terminals 72a, 72b, and 72c. The terminal 72a is connected to the output terminal 110. The terminal 72b is connected to the transmission filter 61T and the terminal 72c is connected to the transmission filter 62T.

In this connection configuration, the switch 72 is capable of connecting the terminal 72a to either of the terminals 72b and 72c based on, for example, a control signal from the RFIC 3. In other words, the connection of the power amplifier circuit 1 is capable of being switched between the transmission filters 61T and 62T with the switch 72. The switch 72 is composed of, for example, a SPDT switch circuit.

The switch 73 is connected between reception filters 61R and 62R and the low-noise amplifier 30. The switch 73 has terminals 73a, 73b, and 73c. The terminal 73a is connected to the low-noise amplifier 30. The terminal 73b is connected to the reception filter 61R and the terminal 73c is connected to the reception filter 62R.

In this connection configuration, the switch 73 is capable of connecting the terminal 73a to either of the terminals 73b and 73c based on, for example, a control signal from the RFIC 3. In other words, the connection of the low-noise amplifier 30 is capable of being switched between the reception filters 61R and 62R with the switch 73. The switch 73 is composed of, for example, a SPDT switch circuit.

The duplexer 61 has a passband including Band A. The duplexer 61 includes the transmission filter 61T and the reception filter 61R and enables frequency division duplex (FDD) in Band A.

The transmission filter 61T (A-Tx) is connected between the power amplifier circuit 1 and the antenna connection terminal 100. Specifically, one end of the transmission filter 61T is connected to the output terminal 110 via the switch 72. The other end of the transmission filter 61T is connected to the antenna connection terminal 100 via the switch 71 and the diplexer 60. The transmission filter 61T has a passband including an uplink operating band of Band A. Accordingly, the transmission filter 61T is capable of transmitting the transmission signal in Band A, among the transmission signals amplified in the power amplifier circuit 1.

The reception filter 61R (A-Rx) is connected between the low-noise amplifier 30 and the antenna connection terminal 100. Specifically, one end of the reception filter 61R is connected to the antenna connection terminal 100 via the switch 71 and the diplexer 60. The other end of the reception filter 61R is connected to the low-noise amplifier 30 via the switch 73. The reception filter 61R has a passband including a downlink operating band of Band A. Accordingly, the reception filter 61R is capable of transmitting the reception signal in Band A, among the reception signals received through the antenna 2.

The duplexer 62 has a passband including Band B. The duplexer 62 includes the transmission filter 62T and the reception filter 62R and enables the FDD in Band B.

The transmission filter 62T (B-Tx) is connected between the power amplifier circuit 1 and the antenna connection terminal 100. Specifically, one end of the transmission filter 62T is connected to the output terminal 110 via the switch 72. The other end of the transmission filter 62T is connected to the antenna connection terminal 100 via the switch 71 and the diplexer 60. The transmission filter 62T has a passband including the uplink operating band of Band B. Accordingly, the transmission filter 62T is capable of transmitting the transmission signal in Band B, among the transmission signals amplified in the power amplifier circuit 1.

The reception filter 62R (B-Rx) is connected between the low-noise amplifier 30 and the antenna connection terminal 100. Specifically, one end of the reception filter 62R is connected to the antenna connection terminal 100 via the switch 71 and the diplexer 60. The other end of the reception filter 62R is connected to the low-noise amplifier 30 via the switch 73. The reception filter 62R has a passband including the downlink operating band of Band B. Accordingly, the reception filter 62R is capable of transmitting the reception signal in Band B, among the reception signals received through the antenna 2.

Band A and Band B are frequency bands for a communication system that is built using a radio access technology (RAT). Band A and Band B are defined in advance by standardizing bodies or the likes (for example, 3rd Generation Partnership Project (3GPP) (registered trademark) and Institute of Electrical and Electronics Engineers (IEEE)). A 5th Generation New Radio (5GNR) system, a Long Term Evolution (LTE) system, a Wireless Local Area Network (WLAN) system, and the like are listed as examples of the communication system.

The diplexer 60 includes a high pass filter 60H and a low pass filter 60L. One terminal of the high pass filter 60H and one terminal of the low pass filter 60L are connected to the antenna connection terminal 100. The other terminal of the high pass filter 60H is connected to the terminal 71a. The high pass filter 60H is a filter having a passband including a first frequency band group including Band A and Band B. The low pass filter 60L is a filter having a passband including a second frequency band group positioned at a low frequency side of the first frequency band group. The diplexer 60 does not necessarily provided.

The matching circuit 41 is connected between the power amplifier circuit 1 and the switch 72 and achieves impedance matching between output impedance of the power amplifier circuit 1 and input impedance of the transmission filters 61T and 62T. The matching circuit 41 is composed of, for example, at least one of an inductor and a capacitor.

The matching circuit 42 is connected between the low-noise amplifier 30 and the switch 73 and achieves impedance matching between input impedance of the low-noise amplifier 30 and output impedance of the reception filters 61R and 62R. The matching circuit 42 is composed of, for example, at least one of an inductor and a capacitor.

The matching circuits 41 and 42 are not necessarily provided. A matching circuit may be arranged between the antenna connection terminal 100 and the duplexer 61 and a matching circuit may be arranged between the antenna connection terminal 100 and the duplexer 62.

The radio-frequency module 6 illustrated in FIG. 1 is only an example and is not limited to this. For example, the radio-frequency module 6 does not necessarily include the duplexer 62 and does not necessarily include the switches 71 to 73. In addition, the radio-frequency module 6 does not necessarily include the reception path and does not necessarily include the low-noise amplifier 30 and the reception filter 61R. For example, the radio-frequency module 6 may include filters and a power amplifier circuit corresponding to Band C, which is different from Band A and Band B.

### [1.3 Circuit Configurations of Power Amplifier Circuit 1 and Power Supply Circuit 5]

Next, the circuit configurations of the power amplifier circuit 1 and the power supply circuit 5 will be described.

FIG. 2 is a circuit block diagram of the power amplifier circuit 1 and the power supply circuit 5 according to the embodiment. As illustrated in FIG. 2, the power amplifier circuit 1 includes the input terminal 120, the output terminal 110, power supply terminals 140 and 150, amplifier transistors 11 and 12, bias circuits 31 and 32, and a PA control circuit 20. In the power amplifier circuit 1, the amplifier transistors 11 and 12 and the bias circuits 31 and 32 compose a power amplifier 10.

The power supply terminals 140 and 150 are terminals for receiving the power supply voltage V_{ET}, which is varied in accordance with an envelope of a radio-frequency input signal input into the power amplifier circuit 1, from the power supply circuit 5.

The amplifier transistor 11 is a bipolar transistor having a base terminal 11B (a first control terminal), a collector terminal 11C (a first terminal), and an emitter terminal 11E (a second terminal). The amplifier transistor 11 is cascade-connected to the amplifier transistor 12 and is arranged upstream of the amplifier transistor 12 (at a drive stage). The base terminal 11B is connected to the input terminal 120, the collector terminal 11C is connected to the power supply terminal 140, and the emitter terminal 11E is grounded. At least one of an inductor and a capacitor may be connected between the base terminal 11B and the input terminal 120, at least one of an inductor and a capacitor may be connected between the collector terminal 11C and the power supply terminal 140, and at least one of an inductor and a capacitor may be connected between the emitter terminal 11E and the ground.

With the above configuration, the amplifier transistor 11 performs power amplification of the radio-frequency input signal input through the input terminal 120 to output the radio-frequency signal subjected to the power amplification from the collector terminal 11C.

The amplifier transistor 11 receives first bias current via the base terminal 11B assuming a first power supply voltage is applied to the power supply terminal 140 and receives second bias current smaller than the first bias current via the base terminal 11B assuming a second power supply voltage higher than the first power supply voltage is applied to the power supply terminal 140.

The amplifier transistor 12 is a bipolar transistor having a base terminal 12B, a collector terminal 12C, and an emitter terminal 12E. The amplifier transistor 12 is arranged downstream of the amplifier transistor 11 (at a power stage). The base terminal 12B is connected to the collector terminal 11C, the collector terminal 12C is connected to the power supply terminal 150 and the output terminal 110, and the emitter terminal 12E is grounded. At least one of an inductor and a capacitor may be connected between the base terminal 12B and the collector terminal 11C, at least one of an inductor and a capacitor may be connected between the collector terminal 12C and the power supply terminal 150, at least one of an inductor and a capacitor may be connected between the collector terminal 12C and the output terminal 110, and at least one of an inductor and a capacitor may be connected between the emitter terminal 12E and the ground.

With the above configuration, the amplifier transistor 12 performs the power amplification of the radio-frequency signal supplied from the collector terminal 11C of the amplifier transistor 11 to output the radio-frequency signal subjected to the power amplification from the collector terminal 12C.

The amplifier transistors 11 and 12 may have, for example, a common collector circuit configuration, instead of the common emitter circuit configuration described above. In addition, the amplifier transistors 11 and 12 are not limited to the bipolar transistors and may be, for example, metal-oxide-semiconductor field-effect transistors (MOSFETs) each having a gate terminal, a drain terminal, and a source terminal.

The bias circuit 31 is an example of a bias circuit and a first bias circuit and is a circuit that supplies bias current Ib1 to the base terminal 11B of the amplifier transistor 11. The bias circuit 31 supplies the first bias current to the base terminal 11B assuming the first power supply voltage is applied to the power supply terminal 140 and supplies the second bias current smaller than the first bias current to the base terminal 11B assuming the second power supply voltage higher than the first power supply voltage is applied to the power supply terminal 140.

The bias circuit 32 is a circuit that supplies bias current Ib2 to the base terminal 12B of the amplifier transistor 12.

Examples of the circuit configurations of the bias circuits 31 and 32 will be described below with reference to FIG. 3.

The PA control circuit 20 is an example of a control circuit and controls the amplifier transistors 11 and 12. For example, the PA control circuit 20 supplies a control signal CTL3 for controlling the bias current Ib1 to be supplied to the amplifier transistor 11 to the bias circuit 31 and supplies a control signal CTL4 for controlling the bias current Ib2 to be supplied to the amplifier transistor 12 to the bias circuit 32.

The power amplifier 10 may include three or more amplifier transistors that include the amplifier transistors 11 and 12 and that are cascade-connected to each other.

The power supply circuit 5 includes a power supply 54, an analog ET tracker 51, a digital ET tracker 52, a switch 53, and a power supply control circuit 50.

The digital ET tracker 52 generates the power supply voltage having multiple discrete voltage levels based on the voltage of the power supply 54. More specifically, the digital ET tracker 52 includes, for example, multiple voltage holding circuits (voltage holding elements) that hold different voltage levels. The digital ET tracker 52 selects one voltage holding circuit from the multiple voltage holding circuits and outputs the power supply voltage of one voltage level from the one selected voltage holding circuit. The digital ET tracker 52 does not necessarily prepare the multiple voltage levels in advance and does not necessarily select and output the voltage level with the switch. For example, the digital ET tracker 52 may generate the voltage level selected from the multiple discrete voltage levels, as needed, to output the power supply voltage of the generated voltage level.

The analog ET tracker 51 generates the power supply voltage having a continuous voltage level based on the voltage of the power supply 54. More specifically, the analog ET tracker 51 has a voltage holding circuit having a variable voltage level and outputs the power supply voltage having a varying voltage level from the voltage holding circuit.

The switch 53 has a common terminal connected to the power supply terminals 140 and 150, a first selection terminal connected to the analog ET tracker 51, and a second selection terminal connected to the digital ET tracker 52. The switch 53 switches between connection between the analog ET tracker 51 and the power supply terminals 140 and 150 and connection between the digital ET tracker 52 and the power supply terminals 140 and 150.

The power supply control circuit 50 selects the voltage level of the power supply voltage V E_{T} used in the power amplifier circuit 1 from the multiple discrete voltage levels, which are generated in the digital ET tracker 52, and continuously varies the voltage level of the power supply voltage V_{ET} to be generated in the analog ET tracker 51, based on an envelope signal of the radio-frequency input signal supplied from the BBIC 4. In addition, the power supply control circuit 50 switches the connection of the switch 53 based on the frequency and the channel band width of the radio-frequency signal input into the power amplifier circuit 1.

The power supply control circuit 50 may control the voltage level of the analog ET tracker 51 so that the power amplitude of the radio-frequency input signal is a linear function of the voltage.

The envelope signal is a signal indicating the envelope of the radio-frequency input signal (modulated waves). The envelope value is represented by, for example, √(I²+Q²). Here, (I, Q) represents a constellation point. The constellation point is a point representing a signal modulated through digital modulation on a constellation diagram. (I, Q) is determined by the BBIC 4 based on, for example, transmission information.

The power supply control circuit 50 is not necessarily included in the power supply circuit 5 and may be included in the RFIC 3.

Next, an example of the circuit configuration of the power amplifier 10 (the bias circuits 31 and 32) will be described.

FIG. 3 is a diagram illustrating the circuit configuration of the power amplifier 10 according to the embodiment. The power amplifier 10 includes the amplifier transistors 11 and 12, the bias circuits 31 and 32, capacitors 141 and 142, and resistive elements 151 and 152.

The capacitors 141 and 142 are direct current (DC)-cut capacitance elements that reduce direct-current components of the radio-frequency signal.

The bias circuit 31 includes a constant current amplifier transistor 310, transistors 311 and 312 that are diode-connected to each other, transistors 316, 317, and 318, a capacitor 313, resistive elements 314, 331, and 332, and a current terminal 315.

The current terminal 315 is a terminal that is connected to the base terminal of the constant current amplifier transistor 310 via the resistive element 314 and that receives constant current from an external circuit. The current terminal 315 may be a constant current source and, in this case, does not necessarily receive the constant current from the external circuit.

The constant current amplifier transistor 310 is an example of a first transistor and has a collector terminal (a third terminal), an emitter terminal (a fourth terminal), and a base terminal (a second control terminal). The constant current amplifier transistor 310 supplies the bias current Ib1 from the emitter terminal to the base terminal 11B of the amplifier transistor 11.

The transistor 318 is an example of a second transistor and has a collector terminal (a fifth terminal), an emitter terminal (a sixth terminal), and a base terminal (a third control terminal). The collector terminal and the base terminal of the transistor 318 are connected to the power supply terminal 140.

The transistor 316 is an example of a third transistor and has a collector terminal (a seventh terminal), an emitter terminal (an eighth terminal), and a base terminal (a fourth control terminal). The collector terminal of the transistor 316 is connected to the base terminal of the constant current amplifier transistor 310 and the base terminal thereof is connected to the emitter terminal of the transistor 318 via the resistive element 332.

The transistor 317 is an example of a fourth transistor and has a collector terminal (a ninth terminal), an emitter terminal (a tenth terminal), and a base terminal (a fifth control terminal). The collector terminal of the transistor 317 is connected to the emitter terminal of the transistor 316 via the resistive element 331 and the emitter terminal thereof is grounded.

The transistor 311 has a collector terminal, an emitter terminal, and a base terminal. The collector terminal and the base terminal of the transistor 311 are connected to the base terminal of the constant current amplifier transistor 310 and the emitter terminal thereof is connected to the collector terminal of the transistor 312.

The transistor 312 has a collector terminal, an emitter terminal, and a base terminal. The collector terminal and the base terminal of the transistor 312 are connected to the emitter terminal of the transistor 311 and the emitter terminal thereof is grounded.

With the above circuit configuration, constant current i1 flowing through the current terminal 315 is input into the base terminal of the constant current amplifier transistor 310. In contrast, current i11 flows from the power supply terminal 140 to the ground through the transistors 318, 316, and 317. In other words, the current input into the base terminal of the constant current amplifier transistor 310 is (i1-i11). The current i11 is first current assuming power supply voltage Vcc1 (V_{ET}) is the first power supply voltage and is second current greater than the first current assuming the power supply voltage Vcc1 (V_{ET}) is the second power supply voltage higher than the first power supply voltage.

The current (i1-i11) input into the base terminal of the constant current amplifier transistor 310 is amplified in the constant current amplifier transistor 310 and is applied from the emitter terminal of the constant current amplifier transistor 310 to the base terminal 11B of the amplifier transistor 11 through the resistive element 151. With this configuration, the bias circuit 31 is capable of outputting the first bias current to the base terminal 11B of the amplifier transistor 11 assuming the power supply voltage Vcc1 (V_{ET}) is the first power supply voltage and is capable of outputting the second bias current smaller than the first bias current to the base terminal 11B of the amplifier transistor 11 assuming the power supply voltage Vcc1 (V_{ET}) is the second power supply voltage higher than the first power supply voltage.

The bias circuit 31 does not necessarily include the transistors 311 and 312, the capacitor 313, and the resistive elements 314, 331, and 332.

The bias circuit 32 supplies the bias current Ib2 to the base terminal 12B of the amplifier transistor 12. More specifically, the bias circuit 32 includes a constant current amplifier transistor 320, transistors 321 and 322 that are diode-connected to each other, a capacitor 323, a resistive element 324, and a current terminal 325.

The current terminal 325 is a terminal that is connected to the base terminal of the constant current amplifier transistor 320 via the resistive element 324 and that receives the constant current from an external circuit. The current terminal 325 may be a constant current source and, in this case, does not necessarily receive the constant current from the external circuit.

The constant current amplifier transistor 320 is a constant current amplifier transistor that has a collector terminal, an emitter terminal, and a base terminal and that supplies the bias current Ib2 from the emitter terminal to the base terminal 12B of the amplifier transistor 12. With this configuration, constant current i2 flowing through the current terminal 325 is supplied to the base terminal of the constant current amplifier transistor 320 and is amplified to be the bias current Ib2. The bias current Ib2 is applied from the emitter terminal of the constant current amplifier transistor 320 to the base terminal 12B of the amplifier transistor 12 through the resistive element 152.

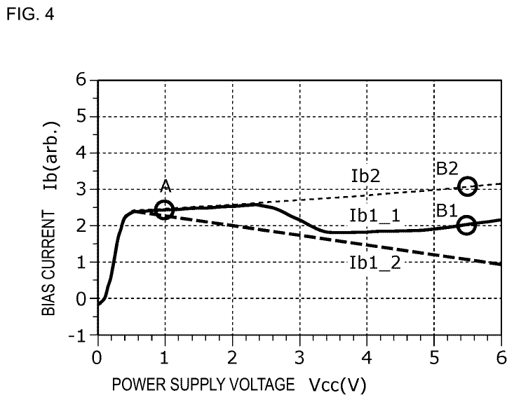

FIG. 4 is a graph indicating the relationship between power supply voltage Vcc and bias current Ib in the power amplifier circuit 1 according to the embodiment. Bias currents Ib11 and Ib12 output from the bias circuit 31 and the bias current Ib2 output from the bias circuit 32 with respect to the variation in the power supply voltage Vcc are indicated in FIG. 4.

The bias current Ib11 indicated in FIG. 4 is generated in the circuit configuration of the bias circuit 31 illustrated in FIG. 3. In the bias current Ib11, the bias current Ib1 is the first bias current (A in FIG. 4) assuming the first power supply voltage (for example, 1 V) is applied to the power supply terminal 140, and the bias current Ib1 is the second bias current (B1 in FIG. 4) smaller than the first bias current (A in FIG. 4) assuming the second power supply voltage (for example, 5.5 V) higher than the first power supply voltage (for example, 1 V) is applied to the power supply terminal 140.

The bias current Ib1 output from the bias circuit 31 may be the bias current Ib12 indicated in FIG. 4. In other words, in the bias current Ib12, the bias current Ib1 to be supplied to the amplifier transistor 11 may monotonically decrease with the increase in the power supply voltage during an interval from the first power supply voltage (for example, 1 V) to the second power supply voltage (for example, 5.5 V).

In this disclosure, “Y monotonically decreases during a certain interval of X” is defined as (1) a value Y2 of Y at the maximum value X2 of X during the certain interval is lower than a value Y1 of Y at the minimum value X1 of X during the certain interval and (2) Y does not monotonically increase during a partial interval defined by two arbitrary points X3 and X4 in the certain interval.

With the bias currents Ib1_1 and Ib1_2 output from the bias circuit 31, it is possible to reduce a gain difference of the amplifier transistor 11 in the digital ET method.

In contrast, the bias current Ib2 indicated in FIG. 4 is generated in the circuit configuration of the bias circuit 32 illustrated in FIG. 3. In the bias current Ib2, the bias current Ib2 is the first bias current (A in FIG. 4) assuming the first power supply voltage (for example, 1 V) is applied to the power supply terminal 150, and the bias current Ib2 is third bias current (B2 in FIG. 4) larger than or equal to the first bias current (A in FIG. 4) assuming the second power supply voltage (for example, 5.5 V) higher than the first power supply voltage (for example, 1 V) is applied to the power supply terminal 150.

The bias current Ib2 output from the bias circuit 32 may have power supply voltage dependence similar to that of the bias current Ib11 or Ib12. With this, it is also possible to reduce the gain difference of the amplifier transistor 12 in the digital ET method.

The amplifier transistor to which the bias current Ib1_1 or Ib1_2 having the power supply voltage dependence indicated in FIG. 4 is supplied may be at least one of one or more amplifier transistors that are cascade-connected to each other and may be the amplifier transistor at either of the drive stage and the power stage.

### [1.4 Description of Digital ET Mode]

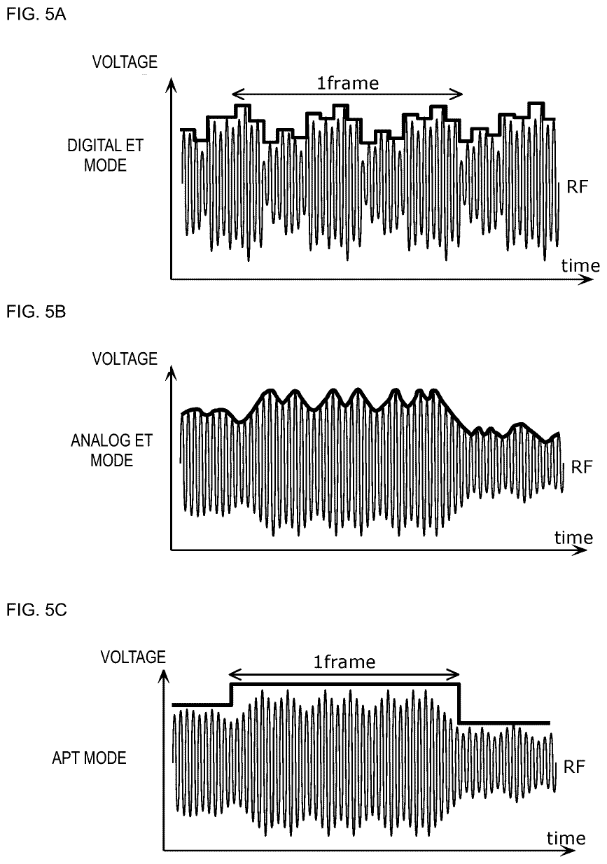

A digital ET mode will now be described with reference to FIG. 5A to FIG. 5C with an ET mode in related art (hereinafter referred to as an analog ET mode) and an average power tracking (APT) mode. FIG. 5A is a graph indicating an example of transition of the power supply voltage in the digital ET mode. FIG. 5B is a graph indicating an example of transition of the power supply voltage in the analog ET mode. FIG. 5C is a graph indicating an example of transition of the power supply voltage in the APT mode. Referring to FIG. 5A to FIG. 5C, the horizontal axis represents time and the vertical axis represents voltage. A bold solid line represents the power supply voltage and a thin solid line (waveform) represents the modulated waves.

In the digital ET mode, the power supply voltage is varied at the multiple discrete voltage levels in one frame to track the envelope of the modulated waves, as indicated in FIG. 5A. As a result, the power supply voltage signal forms rectangular waves. In the digital ET mode, the power supply voltage level is selected or set from the multiple discrete voltage levels based on the envelope signal.

The frame means a unit composing the radio-frequency signal (the modulated waves). For example, in the 5GNR and the LTE, the frame includes 10 sub-frames, each sub-frame includes multiple slots, and each slot is composed of multiple symbols. The sub-frame length is 1 ms and the frame length is 10 ms.

In the analog ET mode, the power supply voltage is continuously varied to track the envelope of the modulated waves, as illustrated in FIG. 5B. The power supply voltage is determined based on the envelope signal in the analog ET mode. In the analog ET mode, it is difficult for the power supply voltage to track the envelope assuming the envelope of the modulated waves is rapidly varied.

In the APT mode, the power supply voltage is varied at the multiple discrete voltage levels in units of frames, as illustrated in FIG. 5C. As a result, the power supply voltage signal forms the rectangular waves. The voltage level of the power supply voltage is determined based on not the envelope signal but the average output power in the APT mode. In the APT mode, the voltage level may be varied in units of, for example, sub-frames, which are smaller than one frame.

### [1.5 Gain Characteristics in Digital ET Mode]

Next, gain characteristics in the digital ET mode of the power amplifier circuit 1 of the present embodiment will be described with reference to a comparative example.

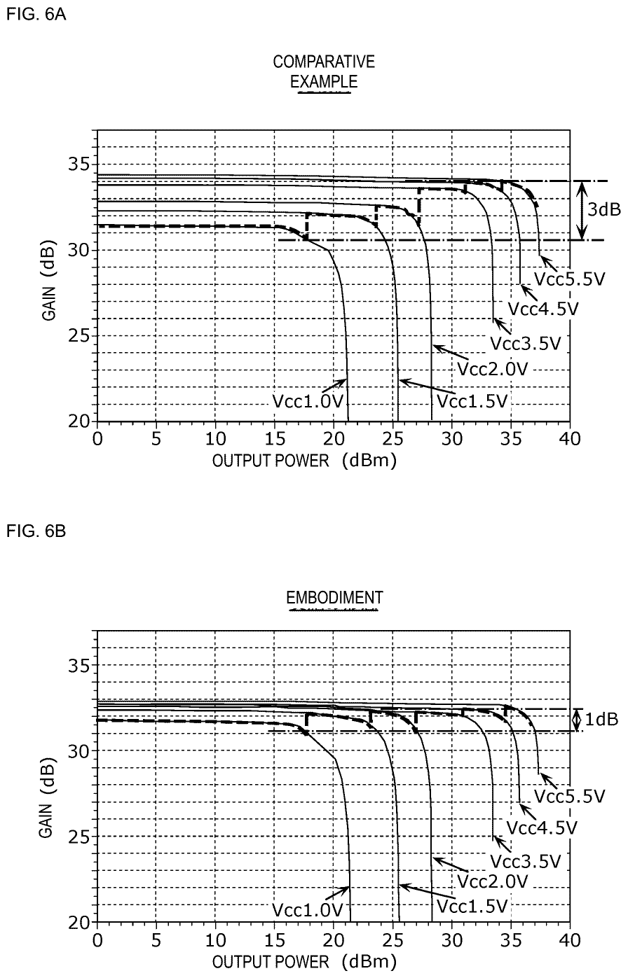

FIG. 6A is a graph indicating the relationship between the output power and the gain in the digital ET mode of a power amplifier circuit according to the comparative example. FIG. 6B is a graph indicating the relationship between the output power and the gain in the digital ET mode of the power amplifier circuit 1 according to the embodiment.

The power amplifier circuit according to the comparative example includes the amplifier transistors 11 and 12, a bias circuit 531, the bias circuit 32, the capacitors 141 and 142, and the resistive elements 151 and 152. The power amplifier circuit according to the comparative example differs from the power amplifier circuit 1 according to the present embodiment only in the bias circuit 531. The bias circuit 531 has the same circuit configuration as that of the bias circuit 32. Specifically, in the bias circuit 531, the bias current Ib1 is the first bias current assuming the first power supply voltage is applied to the power supply terminal 140 and the bias current Ib1 is the third bias current greater than or equal to the first bias current assuming the second power supply voltage higher than the first power supply voltage is applied to the power supply terminal 140.

With the power amplifier circuit according to the comparative example, as illustrated in FIG. 6A, discretely increasing the power supply voltage Vcc with the increase in the output power increases the gain and the difference between the gain assuming the power supply voltage Vcc is 1.0 V and the gain assuming the power supply voltage Vcc is 5.5 V is about 3 dB. Accordingly, since the gain difference of the power amplifier circuit is large, it is supposed that amplification characteristics, such as backoff and signal distortion, are degraded.

In contrast, with the power amplifier circuit 1 according to the present embodiment, as illustrated in FIG. 6B, although discretely increasing the power supply voltage Vcc with the increase in the output power slightly increases the gain, the difference between the gain assuming the power supply voltage Vcc is 1.0 V and the gain assuming the power supply voltage Vcc is 5.5 V is kept at about 1 dB. Accordingly, since the gain difference of the power amplifier circuit 1 is kept at a smaller value, it is possible to suppress the degradation of the amplification characteristics, such as the backoff and the signal distortion.

In the case of the power amplifier circuit according to the comparative example, collector current Ic of the amplifier transistor 11 is increased with the increase in the power supply voltage Vcc to increase the output power output from the collector terminal, thus increasing the gain determined by the ratio between the input power and the output power. In contrast, in the case of the power amplifier circuit 1 according to the present embodiment, since the collector current Ic of the amplifier transistor 11 is not increased by decreasing the bias current in accordance with the increasing power supply voltage Vcc, it is understood that the output power output from the collector terminal is not increased and the increase in the gain is suppressed.

### [1.6 Circuit Configuration of Power Amplifier 10A According to First Modification]

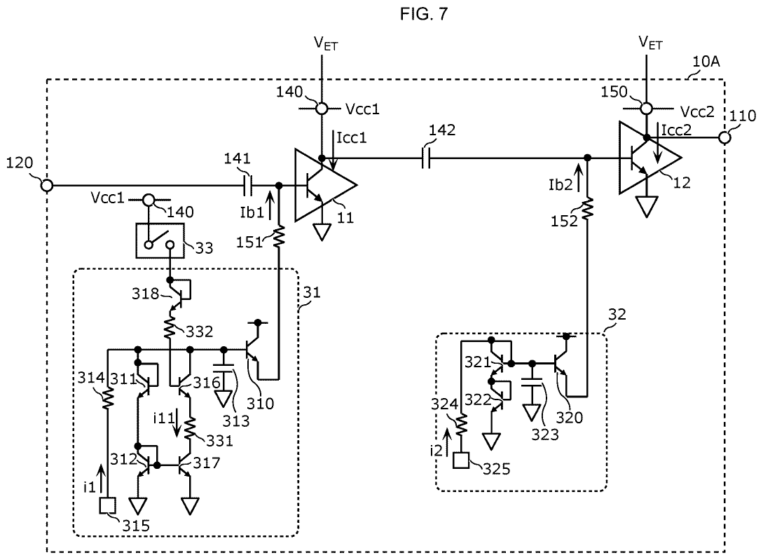

FIG. 7 is a diagram illustrating the circuit configuration of a power amplifier 10A according to a first modification. As illustrated in FIG. 7, the power amplifier 10A includes the amplifier transistors 11 and 12, the bias circuits 31 and 32, a switch 33, the capacitors 141 and 142, and the resistive elements 151 and 152. The power amplifier 10A according to the present modification differs from the power amplifier 10 according to the embodiment in that the power amplifier 10A includes the switch 33. A description of the same components of the power amplifier 10A according to the present modification as those of the power amplifier 10 according to the embodiment is omitted and the following description focuses on components different from the power amplifier 10 according to the embodiment.

The switch 33 is connected between the bias circuit 31 and the power supply terminal 140 and switches between connection and non-connection between the bias circuit 31 and the power supply terminal 140. More specifically, the switch 33 is connected between the collector terminal and the base terminal of the transistor 318 and the power supply terminal 140. The switch 33 is composed of, for example, a single-pole single-throw (SPST) switch element.

With the above configuration, setting the switch 33 to a non-connection state enables flowing of leakage current from the power supply circuit 5 into the amplifier transistor 11 and circuits around the amplifier transistor 11 to be avoided.

The switch 33 may be in a connection state assuming the amplifier transistor 11 is in an on state and the switch 33 may be in the non-connection state assuming the amplifier transistor 11 is in an off state.

With the above configuration, setting the switch 33 to the non-connection state enables occurrence of off-leakage current of the amplifier transistor 11 to be suppressed.

The switch 33 may be in the connection state assuming a first variable power supply voltage having multiple variable discrete voltage levels in the digital ET mode is supplied to the power supply terminal 140 and the switch 33 may be in the non-connection state assuming a second variable power supply voltage that is continuously variable in the analog ET mode is supplied to the power supply terminal 140.

With the above configuration, in the digital ET mode, the bias circuit 31 relatively decreases the bias current Ib1 assuming the power supply voltage Vcc is relatively increased. In contrast, in the analog ET mode, the bias circuit 31 relatively keeps or increases the bias current Ib1 assuming the power supply voltage Vcc is relatively increased. Accordingly, it is possible to reduce the gain difference assuming the output power is varied in both the analog ET mode and the digital ET mode.

The switch 33 may be in the connection state assuming the first variable power supply voltage having multiple variable discrete voltage levels in the digital ET mode is supplied to the power supply terminal 140 and the switch 33 may be in the non-connection state assuming a third variable power supply voltage having multiple variable discrete voltage levels in the APT mode is supplied to the power supply terminal 140.

With the above configuration, in the digital ET mode, the bias circuit 31 relatively decreases the bias current Ib1 assuming the power supply voltage Vcc is relatively increased. In contrast, in the APT mode, the bias circuit 31 relatively keeps or increases the bias current Ib1 assuming the power supply voltage Vcc is relatively increased. Accordingly, it is possible to reduce the gain difference assuming the output power is varied in both the APT mode and the digital ET mode.

Assuming the PA control circuit 20 is formed of a semiconductor integrated circuit (IC) (a first semiconductor IC), the switch 33 may be included in the semiconductor IC. In this case, it is possible to reduce the size of the power amplifier circuit 1.

In contrast, the power supply terminals 140 and 150, the amplifier transistors 11 and 12, and the bias circuits 31 and 32 may be included in a semiconductor IC (a second semiconductor IC) different from the above semiconductor IC.

The semiconductor IC is composed, for example, using complementary metal oxide semiconductor (CMOS). Specifically, the semiconductor IC may be manufactured using a Silicon on Insulator (SOI) process. The semiconductor IC may be made of at least one of gallium arsenide (GaAs), silicon germanium (SiGe), and gallium nitride (GaN). Each of the transistors in the amplifier transistors 11 and 12 and the bias circuits 31 and 32 is, for example, a bipolar transistor, such as a heterojunction bipolar transistor (HBT). The semiconductor material of the semiconductor IC is not limited to the above materials.

### [1.7 Circuit Configuration of Power Amplifier Circuit 1A According to Second Modification]

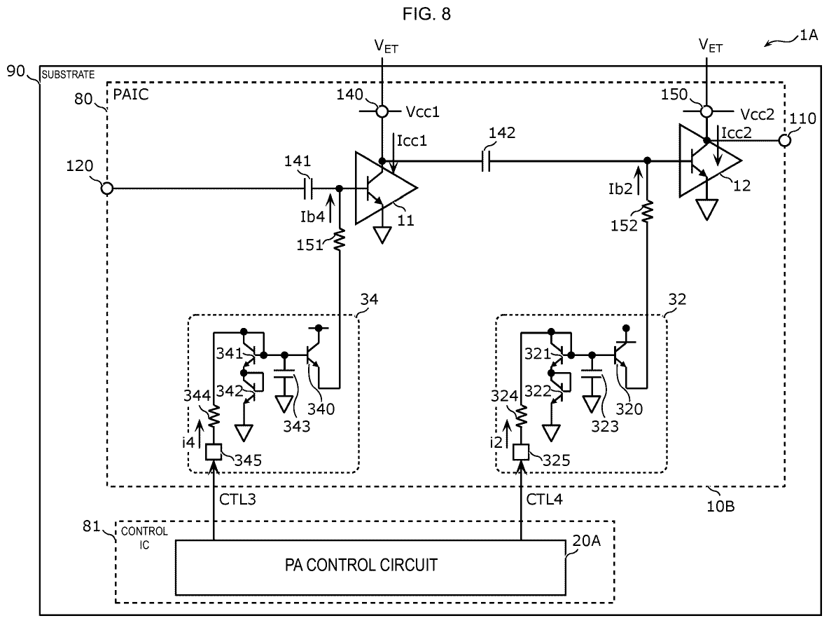

FIG. 8 is a diagram illustrating the circuit configuration of a power amplifier circuit 1A according to a second modification. As illustrated in FIG. 8, the power amplifier circuit 1A includes a power amplifier 10B and a PA control circuit 20A. The power amplifier circuit 1A according to the present modification differs from the power amplifier circuit 1 according to the embodiment in that a bias circuit 34 is arranged, instead of the bias circuit 31, and in the configuration of the PA control circuit 20A. A description of the same components of the power amplifier circuit 1A according to the present modification as those of the power amplifier circuit 1 according to the embodiment is omitted and the following description focuses on components different from the power amplifier circuit 1 according to the embodiment.

The power amplifier 10B includes the amplifier transistors 11 and 12, the bias circuits 34 and 32, the capacitors 141 and 142, and the resistive elements 151 and 152. The power amplifier 10B according to the present modification differs from the power amplifier 10 according to the embodiment in the configuration of the bias circuit 34. A description of the same components of the power amplifier 10B according to the present modification as those of the power amplifier 10 according to the embodiment is omitted and the following description focuses on components different from the power amplifier 10 according to the embodiment.

The bias circuit 34 is an example of a second bias circuit and supplies bias current Ib4 to the base terminal 11B of the amplifier transistor 11. More specifically, the bias circuit 34 includes a constant current amplifier transistor 340, transistors 341 and 342 that are diode-connected to each other, a capacitor 343, a resistive element 344, and a current terminal 345.

The current terminal 345 is a terminal that is connected to the base terminal of the constant current amplifier transistor 340 via the resistive element 344 and that receives the constant current from an external circuit. The current terminal 345 may be a constant current source and, in this case, does not necessarily receive the constant current from the external circuit.

The constant current amplifier transistor 340 is a constant current amplifier transistor that has a collector terminal, an emitter terminal, and a base terminal and that supplies the bias current Ib4 from the emitter terminal to the base terminal 11B of the amplifier transistor 11. With this configuration, constant current i4 flowing through the current terminal 345 is supplied to the base terminal of the constant current amplifier transistor 340 and is amplified to be the bias current Ib4. The bias current Ib4 is applied from the emitter terminal of the constant current amplifier transistor 340 to the base terminal 11B of the amplifier transistor 11 through the resistive element 151.

The PA control circuit 20A is an example of the control circuit. The PA control circuit 20A generates a first control signal (CTL3 in FIG. 8) assuming the first power supply voltage is applied to the power supply terminal 140 and generates a second control signal (CTL3 in FIG. 8) assuming the second power supply voltage higher than the first power supply voltage is applied to the power supply terminal 140. The first control signal and the second control signal are supplied to the current terminal 345. The PA control circuit 20A is formed in a control IC 81 (the first semiconductor IC).

The bias circuit 34 supplies the first bias current to the base terminal 11B assuming the first control signal is supplied to the current terminal 345 and supplies the second bias current smaller than the first bias current to the base terminal 11B assuming the second control signal is supplied to the current terminal 345. The power amplifier 10B is formed in a power amplifier integrated circuit (PAIC) 80 (the second semiconductor IC).

The control IC 81 and the PAIC 80 are arranged on a substrate 90. Although, for example, a low temperature co-fired ceramics (LTCC) substrate or a high temperature co-fired ceramics (HTCC) substrate, which has a laminated structure of multiple dielectric layers, a component-embedded board, a substrate including a redistribution layer (RDL), or a printed circuit board is usable as the module laminate 90, the substrate 90 is not limited to the above ones.

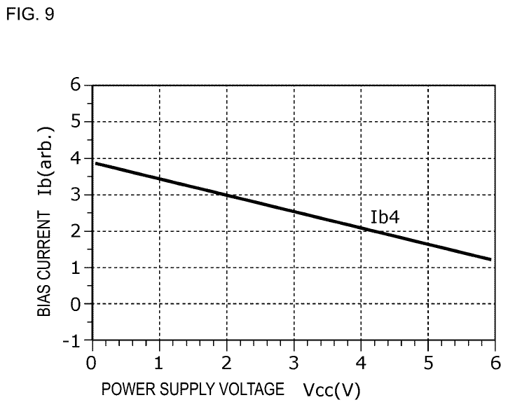

FIG. 9 is a graph indicating the relationship between the power supply voltage Vcc and the bias current Ib in the power amplifier circuit 1A according to the second modification. The bias current Ib4 output from the bias circuit 34 with respect to the variation in the power supply voltage Vcc1 is indicated in FIG. 9.

The bias current Ib4 indicated in FIG. 9 is generated by the bias circuit 34 in response to the control signal (CTL3) output from the PA control circuit 20A illustrated in FIG. 8. The bias current Ib4 is the first bias current assuming the first power supply voltage (for example, 1 V) is applied to the power supply terminal 140 and the bias current Ib4 is the second bias current smaller than the first bias current assuming the second power supply voltage higher than the first power supply voltage is applied to the power supply terminal 140. In the present modification, the bias current Ib4 is decreased as the power supply voltage Vcc1 applied to the power supply terminal 140 is increased.

With the bias current Ib4 output from the bias circuit 34, it is possible to reduce the gain difference of the amplifier transistor 11 in the digital ET method. In addition, since the PA control circuit 20A controls the bias circuit 34, the bias circuits 32 and 34 composing the power amplifier 10B may have the circuit configuration in the related art. Accordingly, it is possible to simplify the circuit configuration of the power amplifier 10B.

In the present modification, the bias current Ib2 output from the bias circuit 32 also has the power supply voltage dependence similar to that of the bias current Ib4. Accordingly, it is also possible to reduce the gain difference of the amplifier transistor 12 in the digital ET method. In other words, the PA control circuit 20A generates a third control signal (CTL4 in FIG. 8) assuming a third power supply voltage is applied to the power supply terminal 150 and generates a fourth control signal (CTL4 in FIG. 8) assuming fourth power supply voltage higher than the third power supply voltage is applied to the power supply terminal 150. The third control signal and the fourth control signal are supplied to the current terminal 325. The bias circuit 32 supplies the third bias current to the base terminal 12B assuming the third control signal is supplied to the current terminal 325 and supplies the fourth bias current smaller than the third bias current to the base terminal 12B assuming the fourth control signal is supplied to the current terminal 325.

The amplifier transistor to which the bias current Ib4 having the power supply voltage dependence indicated in FIG. 9 is supplied may be at least one of one or more amplifier transistors that are cascade-connected to each other and may be the amplifier transistor at either of the drive stage and the power stage.

### [2. Features and so On]

As described above, the power amplifier circuit 1 according to the present embodiment includes the power supply terminal 140, and the amplifier transistor 11 that has the base terminal 11B, the collector terminal 11C connected to the power supply terminal 140, and the emitter terminal 11E and that performs the power amplification of the radio-frequency input signal input through the base terminal 11B to output the radio-frequency signal subjected to the power amplification from the collector terminal 11C. The amplifier transistor 11 receives the first bias current via the base terminal 11B assuming the first power supply voltage is applied to the power supply terminal 140. The amplifier transistor 11 receives the second bias current smaller than the first bias current via the base terminal assuming the second power supply voltage higher than the first power supply voltage is applied to the power supply terminal 140.

With the above configuration, since the gain difference of the power amplifier circuit 1 assuming the power supply voltage Vcc is discretely increased with the increase in the output power is capable of being reduced, it is possible to suppress the degradation of the amplification characteristics, such as the backoff and the signal distortion.

For example, in the power amplifier circuit 1, the bias current to be supplied to the amplifier transistor 11 may monotonically decrease with increase in the power supply voltage during an interval from the first power supply voltage to the second power supply voltage.

With the above configuration, it is possible to further reduce the gain difference of the power amplifier circuit 1 during the above interval of the power supply voltage.

For example, the power amplifier circuit 1 may further include the bias circuit 31 that supplies the first bias current to the base terminal 11B assuming the first power supply voltage is applied to the power supply terminal 140 and that supplies the second bias current to the base terminal 11B assuming the second power supply voltage is applied to the power supply terminal 140.

For example, the power amplifier circuit 1A according to the second modification may further include the PA control circuit 20A that generates the first control signal assuming the first power supply voltage is applied to the power supply terminal 140 and that generates the second control signal assuming the second power supply voltage higher than the first power supply voltage is applied to the power supply terminal 140, and the bias circuit 34 that supplies the first bias current to the base terminal 11B assuming the first control signal is supplied and that supplies the second bias current smaller than the first bias current to the base terminal 11B assuming the second control signal is supplied.

With the above configuration, since the PA control circuit 20A controls the bias circuit 34, the bias circuits composing the power amplifier 10B may have the circuit configuration in the related art. Accordingly, it is possible to simplify the circuit configuration of the power amplifier 10B.

For example, in the power amplifier circuit 1A, the PA control circuit 20A is included in the control IC 81 and the amplifier transistor 11 and the bias circuit 34 are included the PAIC 80.

With the above configuration, since each of the PA control circuit 20A and the power amplifier 10B are included in the IC, it is possible to reduce the size of the power amplifier circuit 1A.

The power amplifier circuit 1 according to the present embodiment includes the power supply terminal 140, the amplifier transistor 11 that has the base terminal 11B, the collector terminal 11C connected to the power supply terminal 140, and the emitter terminal 11E and that performs the power amplification of the radio-frequency input signal input through the base terminal 11B to output the radio-frequency signal subjected to the power amplification from the collector terminal 11C, and the bias circuit 31 that outputs the bias current. The bias circuit 31 includes the constant current amplifier transistor 310 that supplies the bias current from the emitter terminal to the base terminal 11B of the amplifier transistor 11, the current terminal 315 that is connected to the base terminal of the constant current amplifier transistor 310 and that receives the constant current, the transistor 318 the collector terminal and the base terminal of which are connected to the power supply terminal 140, the transistor 316 the collector terminal of which is connected to the base terminal of the constant current amplifier transistor 310 and the base terminal of which is connected to the emitter terminal of the transistor 318, and the transistor 317 the collector terminal of which is connected to the emitter terminal of the transistor 316 and the emitter terminal of which is grounded.

With the above configuration, the constant current i1 flowing through the current terminal 315 is input into the base terminal of the constant current amplifier transistor 310. In contrast, the current i11 flows from the power supply terminal 140 to the ground through the transistors 318, 316, and 317. In other words, the current input into the base terminal of the constant current amplifier transistor 310 is (i1-i11). The current i11 is the first current assuming the power supply voltage Vcc1 (V_{ET}) is the first power supply voltage and is the second current greater than the first current assuming the power supply voltage Vcc1 (V_{ET}) is the second power supply voltage higher than the first power supply voltage. The current (i1-i11) input into the base terminal of the constant current amplifier transistor 310 is amplified in the constant current amplifier transistor 310 and is applied from the emitter terminal of the constant current amplifier transistor 310 to the base terminal 11B of the amplifier transistor 11 through the resistive element 151. With this configuration, the bias circuit 31 is capable of outputting the first bias current to the base terminal 11B of the amplifier transistor 11 assuming the power supply voltage Vcc1 (V_{ET}) is the first power supply voltage and is capable of outputting the second bias current smaller than the first bias current to the base terminal 11B of the amplifier transistor 11 assuming the power supply voltage Vcc1 (V_{ET}) is the second power supply voltage higher than the first power supply voltage. Accordingly, since the gain difference of the power amplifier circuit 1 assuming the power supply voltage Vcc is discretely increased with the increase in the output power is capable of being reduced, it is possible to suppress the degradation of the amplification characteristics, such as the backoff and the signal distortion.

For example, the power amplifier 10A according to the first modification may further include the switch 33 that is connected between the collector terminal and the base terminal of the transistor 318 and the power supply terminal 140.

With the above configuration, setting the switch 33 to the non-connection state enables flowing of the leakage current from the power supply circuit 5 into the amplifier transistor 11 and circuits around the amplifier transistor 11 to be avoided.

For example, the power amplifier circuit 1 may further include the PA control circuit 20 that controls the amplifier transistor 11. The PA control circuit 20 and the switch 33 may be included in the first semiconductor IC.

With the above configuration, it is possible to reduce the size of the power amplifier circuit including the power amplifier 10A and the PA control circuit.

For example, in the power amplifier 10A, the switch 33 may be in the connection state assuming the amplifier transistor 11 is in the on state and the switch 33 may be in the non-connection state assuming the amplifier transistor 11 is in the off state.

With the above configuration, setting the switch 33 to the non-connection state enables occurrence of the off-leakage current of the amplifier transistor 11 to be suppressed.

For example, in the power amplifier 10A, the first variable power supply voltage having multiple variable discrete voltage levels in one frame of the radio-frequency input signal and the second variable power supply voltage that is continuously variable may be supplied to the amplifier transistor 11. The switch 33 may be in the connection state assuming the first variable power supply voltage is applied to the power supply terminal 140 and the switch 33 may be in the non-connection state assuming the second variable power supply voltage is applied to the power supply terminal 140.

With the above configuration, in the digital ET mode, the bias circuit 31 relatively decreases the bias current Ib1 assuming the power supply voltage Vcc is relatively increased. In contrast, in the analog ET mode, the bias circuit 31 relatively keeps or increases the bias current Ib1 assuming the power supply voltage Vcc is relatively increased. Accordingly, it is possible to reduce the gain difference assuming the output power is varied in both the analog ET mode and the digital ET mode.

For example, in the power amplifier 10A, the first variable power supply voltage having multiple variable discrete voltage levels in one frame of the radio-frequency input signal and the third variable power supply voltage having multiple variable discrete voltage levels in units of frames of the radio-frequency input signal may be supplied to the amplifier transistor 11. The switch 33 may be in the connection state assuming the first variable power supply voltage is applied to the power supply terminal 140 and the switch 33 may be in the non-connection state assuming the third variable power supply voltage is applied to the power supply terminal 140.

With the above configuration, in the digital ET mode, the bias circuit 31 relatively decreases the bias current Ib1 assuming the power supply voltage Vcc is relatively increased. In contrast, in the APT mode, the bias circuit 31 relatively keeps or increases the bias current Ib1 assuming the power supply voltage Vcc is relatively increased. Accordingly, it is possible to reduce the gain difference assuming the output power is varied in both the APT mode and the digital ET mode.

For example, in the power amplifier circuit 1, the power supply terminal 140, the amplifier transistor 11, and the bias circuit 31 may be included in the second semiconductor IC.

With the above configuration, it is possible to reduce the size of the power amplifier 10.

The communication device 7 according to the embodiment includes the RFIC 3 that processes the radio-frequency signal, and the power amplifier circuit 1 that transmits the radio-frequency signal between the RFIC 3 and antenna 2.

With the above configuration, it is possible to realize the features of the power amplifier circuit 1 in the communication device 7.

### OTHER EMBODIMENTS

Although the power amplifier circuits and the communication device according to the present disclosure are described based on the embodiments and the modifications, the power amplifier circuits and the communication device according to the present disclosure are not limited to the above embodiments and modifications. Other examples realized by combining arbitrary components in the above embodiments and modifications, modifications achieved by making various modifications supposed by the person skilled in the art to the above embodiments and modifications without departing from the spirit and scope of the present disclosure, and various devices incorporating the power amplifier circuits and the communication device described above are also included in the present disclosure.

For example, in the circuit configurations of the power amplifier circuits and the communication device according to the above embodiments and modifications, other circuit elements, lines, and so on may be provided between the paths with which the respective circuit elements and signal paths disclosed in the drawings are connected.

### INDUSTRIAL APPLICABILITY

The present disclosure is widely usable for a communication device, such as a mobile phone, as the power amplifier circuit or the communication device arranged in a multiband front-end unit.

### REFERENCE SIGNS LIST

1, 1A power amplifier circuit
2 antenna
3 RFIC
4 BBIC
5 power supply circuit
6 radio-frequency module
7 communication device
10, 10A, 10B power amplifier
11, 12 amplifier transistor
11B, 12B base terminal
11C, 12C collector terminal
11E, 12E emitter terminal
20, 20A PA control circuit
30 low-noise amplifier
31, 32, 34, 531 bias circuit
33, 53, 71, 72, 73 switch
41, 42 matching circuit
50 power supply control circuit
51 analog ET tracker
52 digital ET tracker
54 power supply
60 diplexer
60H high pass filter
60L low pass filter
61, 62 duplexer
61R, 62R reception filter
61T, 62T transmission filter
71a, 71b, 71c, 72a, 72b, 72c, 73a, 73b, 73c terminal
80 PAIC
81 control IC
90 substrate
100 antenna connection terminal
110 output terminal
120 input terminal
130 control terminal
140, 150 power supply terminal
141, 142, 313, 323, 343 capacitor
151, 152, 314, 324, 331, 332, 344 resistive element
310, 320, 340 constant current amplifier transistor
311, 312, 316, 317, 318, 321, 322, 341, 342 transistor
315, 325, 345 current terminal

1. A power amplifier circuit comprising:
a power supply terminal; and
an amplifier transistor that has a first control terminal, a first terminal connected to the power supply terminal, and a second terminal and that performs power amplification of a radio-frequency input signal input through the first control terminal to output a radio-frequency signal subjected to the power amplification from the first terminal,
wherein the amplifier transistor receives first bias current via the first control terminal assuming a first power supply voltage is applied to the power supply terminal, and
wherein the amplifier transistor receives second bias current smaller than the first bias current via the first control terminal assuming a second power supply voltage higher than the first power supply voltage is applied to the power supply terminal.

2. The power amplifier circuit according to claim 1,
wherein the bias current to be supplied to the amplifier transistor monotonically decreases with increase in the power supply voltage during an interval from the first power supply voltage to the second power supply voltage.

3. The power amplifier circuit according to claim 2, further comprising:
a first bias circuit that supplies the first bias current to the first control terminal assuming the first power supply voltage is applied to the power supply terminal and that supplies the second bias current to the first control terminal assuming the second power supply voltage is applied to the power supply terminal.

4. The power amplifier circuit according to claim 2, further comprising:
a control circuit that generates a first control signal assuming the first power supply voltage is applied to the power supply terminal and that generates a second control signal assuming the second power supply voltage is applied to the power supply terminal; and
a second bias circuit that supplies the first bias current to the first control terminal assuming the first control signal is supplied and that supplies the second bias current to the first control terminal assuming the second control signal is supplied.

5. The power amplifier circuit according to claim 4,
wherein the control circuit is included in a first semiconductor integrated circuit, and
wherein the amplifier transistor and the second bias circuit are included in a second semiconductor integrated circuit.

6. A power amplifier circuit comprising:
a power supply terminal;
an amplifier transistor that has a first control terminal, a first terminal connected to the power supply terminal, and a second terminal and that performs power amplification of a radio-frequency input signal input through the first control terminal to output a radio-frequency signal subjected to the power amplification from the first terminal; and
a bias circuit that outputs bias current,
wherein the bias circuit includes
a first transistor that has a third terminal, a fourth terminal, and a second control terminal and that supplies the bias current from the fourth terminal to the first control terminal,
a current terminal that is connected to the second control terminal and that receives constant current,
a second transistor which has a fifth terminal, a sixth terminal, and a third control terminal and the fifth terminal and the third control terminal of which are connected to the power supply terminal,
a third transistor which has a seventh terminal, an eighth terminal, and a fourth control terminal, the seventh terminal of which is connected to the second control terminal, and the fourth control terminal of which is connected to the sixth terminal, and
a fourth transistor which has a ninth terminal, a tenth terminal, and a fifth control terminal, the ninth terminal of which is connected to the eighth terminal, and the tenth terminal of which is grounded.

7. The power amplifier circuit according to claim 6,
wherein the bias circuit supplies first bias current to the first control terminal assuming a first power supply voltage is applied to the power supply terminal, and
wherein the bias circuit supplies second bias current smaller than the first bias current to the first control terminal assuming a second power supply voltage higher than the first power supply voltage is applied to the power supply terminal.

8. The power amplifier circuit according to claim 7,
wherein the bias current to be supplied to the amplifier transistor monotonically decreases with increase in the power supply voltage during an interval from the first power supply voltage to the second power supply voltage.

9. The power amplifier circuit according to claim 8, further comprising:
a switch that is connected between the fifth terminal and the third control terminal and the power supply terminal and that switches between connection and non-connection between the fifth terminal and the third control terminal and the power supply terminal.

10. The power amplifier circuit according to claim 9, further comprising:
a control circuit that controls the amplifier transistor,
wherein the control circuit and the switch are included in a first semiconductor integrated circuit.

11. The power amplifier circuit according to claim 10,
wherein the switch is in a connection state assuming the amplifier transistor is in an on state, and
wherein the switch is in a non-connection state assuming the amplifier transistor is in an off state.

12. The power amplifier circuit according to claim 11,
wherein a first variable power supply voltage having multiple variable discrete voltage levels in one frame of the radio-frequency input signal and a second variable power supply voltage that is continuously variable are supplied to the amplifier transistor,
wherein the switch is in a connection state assuming the first variable power supply voltage is applied to the power supply terminal, and
wherein the switch is in a non-connection state assuming the second variable power supply voltage is applied to the power supply terminal.

13. The power amplifier circuit according to claim 11,
wherein a first variable power supply voltage having multiple variable discrete voltage levels in one frame of the radio-frequency input signal and a third variable power supply voltage having multiple variable discrete voltage levels in units of frames of the radio-frequency input signal are supplied to the amplifier transistor,
wherein the switch is in a connection state assuming the first variable power supply voltage is applied to the power supply terminal, and
wherein the switch is in a non-connection state assuming the third variable power supply voltage is applied to the power supply terminal.

14. The power amplifier circuit according to claim 13,
wherein the power supply terminal, the amplifier transistor, and the bias circuit are included in a second semiconductor integrated circuit.

15. A communication device comprising:
a signal processing circuit that processes a radio-frequency signal; and
the power amplifier circuit according to claim 14, which transmits the radio-frequency signal between the signal processing circuit and an antenna.

16. The power amplifier circuit according to claim 1, further comprising:
a first bias circuit that supplies the first bias current to the first control terminal assuming the first power supply voltage is applied to the power supply terminal and that supplies the second bias current to the first control terminal assuming the second power supply voltage is applied to the power supply terminal.

17. The power amplifier circuit according to claim 1, further comprising:
a control circuit that generates a first control signal assuming the first power supply voltage is applied to the power supply terminal and that generates a second control signal assuming the second power supply voltage is applied to the power supply terminal; and
a second bias circuit that supplies the first bias current to the first control terminal assuming the first control signal is supplied and that supplies the second bias current to the first control terminal assuming the second control signal is supplied.

18. The power amplifier circuit according to claim 17,
wherein the control circuit is included in a first semiconductor integrated circuit, and
wherein the amplifier transistor and the second bias circuit are included in a second semiconductor integrated circuit.

19. The power amplifier circuit according to claim 6, further comprising:
a switch that is connected between the fifth terminal and the third control terminal and the power supply terminal and that switches between connection and non-connection between the fifth terminal and the third control terminal and the power supply terminal.

20. The power amplifier circuit according to claim 7, further comprising:
a switch that is connected between the fifth terminal and the third control terminal and the power supply terminal and that switches between connection and non-connection between the fifth terminal and the third control terminal and the power supply terminal.
